(19) United States
(12) Patent Application Publication
(10) Pub. No.: US 2012/0229961 A1
(43) Pub. Date: Sep. 13, 2012

(54) HOUSING OF ELECTRONIC DEVICE AND METHOD FOR MAKING THE SAME

(75) Inventors: YONG-GANG ZHU, Shenzhen City (CN); ZHU-SHA WENG, Shenzhen City (CN); XIN-WU GUAN, Shenzhen City (CN); PO-FENG HO, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/089,422

(22) Filed: Apr. 19, 2011

(30) Foreign Application Priority Data
Mar. 11, 2011 (CN) 201110058498.3

(51) Int. Cl. H05K 5/02; H05K 13/00

(52) U.S. Cl. 361/679.01; 216/37

(57) ABSTRACT

Housing of electronic device includes a metal base and a ceramic pattern portion formed in the exterior surface of the base; The pattern portion is formed by etching of base and enamel of the etched area of the base. The disclosure also described a method to make the housing.

### CROSS-REFERENCE TO RELATED APPLICATIONS

This application is related to co-pending U.S. Patent Application (Attorney Docket No. US36895) entitled “HOUSING OF ELECTRONIC DEVICE AND METHOD FOR MAKING THE SAME”. Such application has the same assignee as the present application. The above-identified application is incorporated herein by reference.

### BACKGROUND

1. Technical Field

The present disclosure relates to housings of electronic devices and a method for making the same.

2. Description of the Related Art

Patterns on housings of electronic devices may be formed by printing or painting. However, these patterns cannot strongly bond to the surface of the housing, and can easily be worn or scraped off.

Therefore, there is room for improvement within the art.

### BRIEF DESCRIPTION OF THE DRAWINGS

Many aspects of the present housing of electronic device and method for making the same can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a front isometric view of a housing of an electronic device according to an exemplary embodiment.

FIG. 2 is a sectional schematic view of the housing shown in FIG. 1 along a line II-II.

FIG. 3 is a sectional schematic view of a metal base be etched.

FIG. 4 is a sectional schematic view of the metal base be enameled.

### DETAILED DESCRIPTION

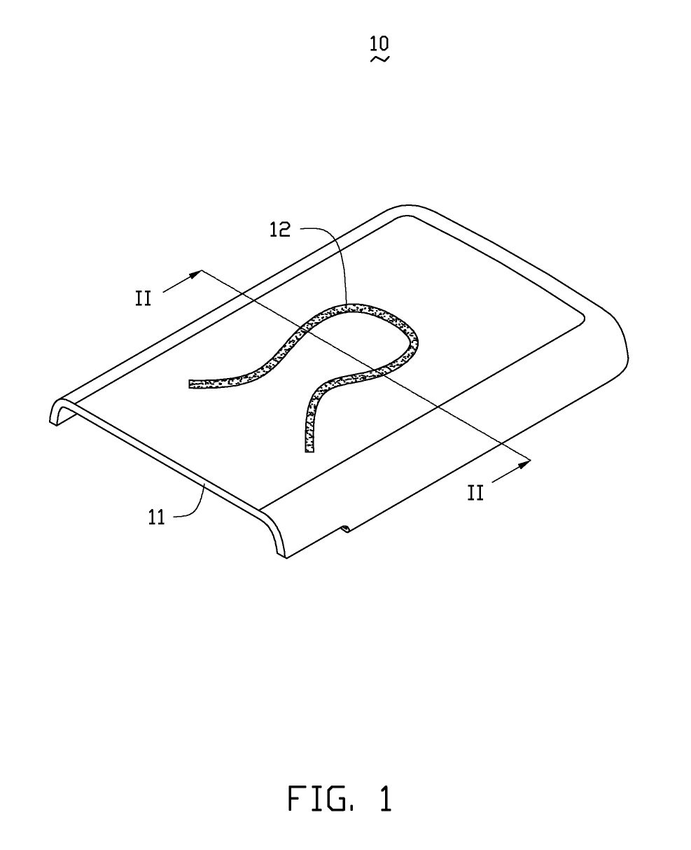

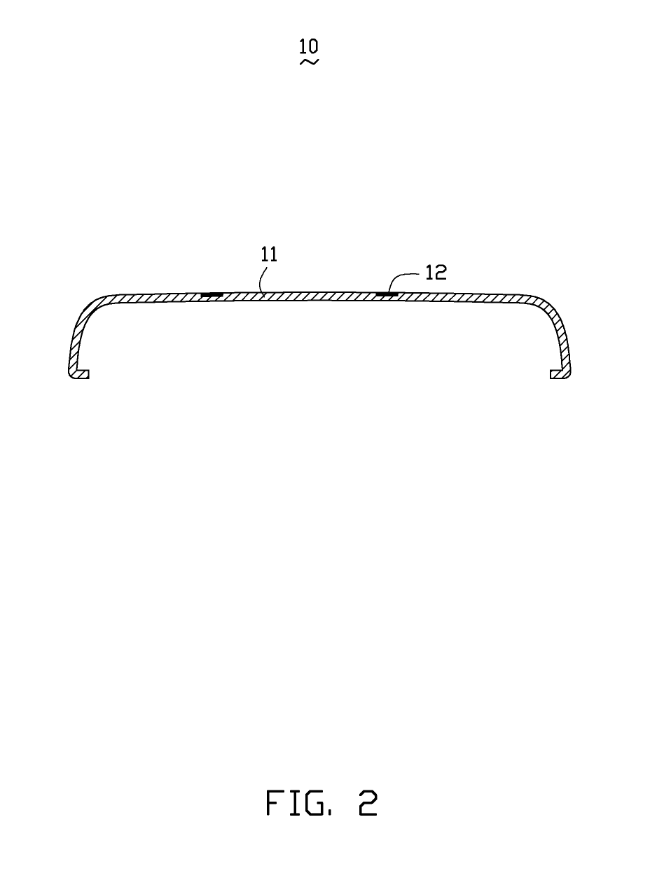

FIGS. 1 and 2 show an exemplary embodiment of a housing 100 of an electronic device such as a mobile phone. The housing 100 includes a metal base 11 and a pattern portion 12 embedded in the exterior surface of the base 11. The base 11 can be stainless steel with a thickness of 0.5 mm (millimeter) or more, and is about 0.5 mm thick in this exemplary embodiment. The pattern portion 12 is comprised of ceramics and has a depth in a range from 0.16 mm to about 0.18 mm, and is about 0.17 mm deep in this exemplary embodiment.

A method to fabricate the housing 10 includes following steps,

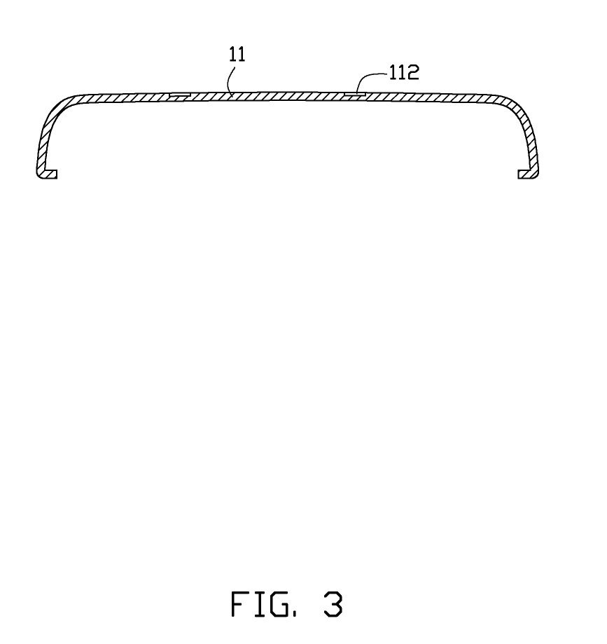

Step 1, referring to FIG. 3, is to etch grooves 112 in the exterior surface of the metal base 11. The metal base 11 is provided and can be stainless steel with a thickness of 0.5 mm. Then, the base 11 is etched to define grooves 112 corresponding to the shape of the pattern portion 12. The grooves 112 have a uniform depth of 0.16 mm-0.18 mm.

Step 2, referring to FIG. 3, is to abrade the bottom of the grooves 112. Before abrading the bottom of the grooves 112, the base 11 is cleaned to remove any contaminants such as grease from the surface of the base 11. A conventional cleaning solution such as oxalic acid, or sodium hydroxide (NaOH) may be used to clean the surface of the base 11. Then, the bottoms of the grooves 112 are abraded by, for example, sand-blasting. During abrading, the adjacent areas of the grooves 112 are shielded and are not abraded. The blasting material used may be comprised of emery, chromium iron alloy, copper ore, quartz sand, or ceramic base sand.

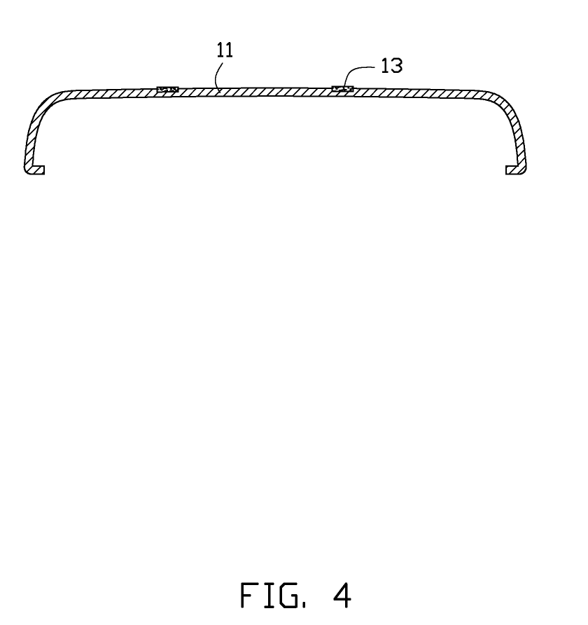

Step 3 is to enamel the grooves 112. The enamel may be applied in two steps, glazing then baking. During glazing, the enamel glaze may comprise inorganic silicate and is electrically conductive. The glaze is evenly arranged on the bottom of the grooves 112, and then the base 11 is placed in an electrical field, causing the base 11 and the glaze to be oppositely charged and thereby form a bond. The thickness of the glaze can be adjusted by adjusting the intensity of the electrical field. During baking, the base 11 is placed into an oven and heated, and the glaze is melted evenly, and firmly combined in the grooves 112. When the glaze melts, it may overflow from the grooves 112 and form a protrusion layer 13 (shown in FIG. 4). Then, the oven is allowed to cool and then the base 11 is taken out from the oven.

Step 4 is to grind and remove the protrusion layer 13 cleanly exposing the pattern portion 12. A typical grinding wheel mechanism can be used to grind the protrusion layer 13. The grinding process includes a preliminary grinding and a detailed grinding. The preliminary grinding is to remove the protrusion layer 13 and expose the pattern portion 12. After the preliminary grinding, detailed grinding is done to ensure the surface of the pattern portion is on the same plane as the surrounding surfaces, and to smooth over any rough tracks left by the preliminary grinding.

Step 5 is to polish the area of the pattern portion 12. During polishing, a polishing material and a polishing solution are used, the polishing material can be a cerium oxide, and the polishing solution mainly be comprised of silicon dioxide and H₂O, with the silicon dioxide having a weight percentage 25% and the H₂O having a weight percentage 75%.

Step 6 can be implemented by sand blasting to roughen areas near the pattern portion 12, to contrast with the pattern portion 12 so that it stands out more for aesthetic reasons if needed. Thus, the housing 10 is fabricated.

It is to be understood that even though numerous characteristics and advantages of the present embodiments have been set forth in the foregoing description, together with details of assemblies and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A housing of electronic device, comprising,
a metal base; and
a ceramic pattern portion formed in the exterior surface of the base;
wherein the pattern portion is formed by etching grooves in the base, and enameling the grooves.

2. The housing of electronic device as claimed in claim 1, wherein a thickness of the base is at least 0.5 millimeter (mm)

3. The housing of electronic device as claimed in claim 1, wherein a depth of the pattern portion is in a range of 0.16 mm-0.18 mm.

4. A method for making a housing of electronic device, comprising, providing a metal base;
etching the base to define grooves thereon;
enameling the grooves, accordingly forming a protrusion layer protruding from the grooves;
grinding and removing the protrusion layer to expose a pattern portion on the base.

5. The method for making a housing of electronic device as claimed in claim 4, wherein further comprising abrading the bottom of the grooves before enameling the grooves.

6. The method for making a housing of electronic device as claimed in claim 5, wherein further comprising cleaning the base to remove contaminants on the surface of the base before abrading the grooves.

7. The method for making a housing of electronic device as claimed in claim 5, wherein enameling the base comprises glazing on the abraded surface and baking.

8. The method for making a housing of electronic device as claimed in claim 7, wherein during glazing, an enamel glaze is evenly arranged on the bottom of the grooves, the metal base is placed into an electrical field, cause the base and the enamel glaze to be oppositely charged and thereby bonding together.

9. The method for making a housing of electronic device as claimed in claim 8, wherein during baking, the enamel glaze is melted evenly and overflow from the grooves to form the protrusion layer.

10. The method for making a housing of electronic device as claimed in claim 4, wherein the grinding process includes preliminary grinding and detailed grinding, the preliminary grinding is to remove protrusion layer and expose the pattern portion, the detailed grinding is to eliminate any tracks left by the preliminary grinding.

11. The method for making a housing of electronic device as claimed in claim 4, wherein further comprising polishing the pattern portion after grinding the protrusion layer.

12. The method for making a housing of electronic device as claimed in claim 4, wherein further comprising processing the adjacent area of the pattern portion after polishing the pattern portion.

13. The method for making a housing of electronic device as claimed in claim 12, wherein the adjacent area is processed by sand blasting.
